(19) United States
(12) Patent Application Publication
(10) Pub. No.: US 2026/0258322 A1
(43) Pub. Date: Sep. 3, 2026

(54) RINSE COMPOSITION AND MANUFACTURING METHOD OF DEVICE USING THE SAME

(71) Applicant: DONGWOO FINE-CHEM CO., LTD., Iksan-si (KR)

(72) Inventors: Ji-Min CHUN, Iksan-si (KR); Yong-Hwan CHO, Iksan-si (KR); Ye-Rin RYU, Iksan-si (KR); Shi-Yong YI, Iksan-si (KR); Jong-Hwan KIM, Iksan-si (KR)

(73) Assignee: DONGWOO FINE-CHEM CO., LTD., Iksan-si (KR)

(21) Appl. No.: 19/552,159

(22) Filed: Feb. 27, 2026

(30) Foreign Application Priority Data
Feb. 28, 2025 (KR) 10-2025-0026996

(51) Int. Cl. C11D 1/825; C11D 1/66; G03F 7/42

(52) U.S. Cl. CPC C11D 1/825; C11D 1/66; G03F 7/422

(57) ABSTRACT

The present disclosure relates to a rinse composition including: a primary alcohol having 2 to 6 carbon atoms, a glycerol ether compound, a diol compound, and water, wherein the glycerol ether compound includes a compound represented by Chemical Formula 1, and the diol compound includes a compound represented by Chemical Formula 2. The rinse composition according to the present disclosure can secure excellent cleaning performance for resist residues while preventing damage to a pattern, such as pattern collapse, when performing a rinsing process for a micropattern formed in a photoresist process.

### CROSS-REFERENCE TO RELATED APPLICATION(S)

This application claims the benefit under 35 USC 119 (a) of Korean Patent Application No. KR 10-2025-0026996, filed on Feb. 28, 2025 with the Korean Intellectual Property Office, the disclosure of which is incorporated herein by reference in its entirety.

### BACKGROUND

### 1. Technical Field

The present disclosure relates to a rinse composition, and a method for manufacturing a device using the same.

### 2. Related Art

A process for forming a pattern by utilizing photolithography is used as a process for forming a fine structure in a semiconductor process, wherein the process is specifically based on a polarity change and a crosslinking reaction of a polymer caused by a photoreaction. In particular, the pattern formation utilizes a characteristic of a change in solubility of a photosensitive resin composition in a solvent such as an aqueous alkaline solution after exposure.

Recently, as an aspect ratio of a pattern has increased in order to form a fine structure in a semiconductor process, when an exposed portion is developed using a developer and then generally rinsed with deionized water and dried, pattern collapse occurs due to a capillary force of water droplets pulling a micropattern during the drying process. In order to solve such a problem, a process for reducing pattern defects occurring during cleaning and drying processes through a rinsing step using a composition having a lower surface tension is being applied after treatment with a developer.

In addition, an effect of improving an overall process margin of a photolithography process by increasing resolution of a formed micropattern by removing development residue not completely removed by a developer in a rinsing step after development has also been reported, and thus a composition used in the rinsing step has been required to have a proper cleaning power so as to remove the residue on a bottom surface of a photoresist pattern. However, approaching from this perspective causes a problem of dissolving a photoresist pattern formed of an organic compound, especially a polymer compound, and deforming the pattern itself, and thus, it is important that a rinse composition does not cause damage to the photoresist pattern.

Japanese Patent Laid-Open Publication No. 2023-147904 discloses a cleaner composition for textile products. However, when a rinsing process is performed using the composition, there are limitations in that it not only causes damage to a photoresist pattern but also induces pattern collapse.

### PRIOR ART DOCUMENTS

### Patent Documents

(Patent Document 1) Japanese Patent Laid-Open Publication No. 2023-147904

### SUMMARY

The present disclosure has been made to solve the problems of the prior art described above, and an object thereof is to provide a rinse composition capable of securing excellent cleaning performance for resist residues while preventing damage to a pattern, such as pattern collapse, when performing a rinsing process for a micropattern formed in a photoresist process.

Another object of the present disclosure is to provide a method for manufacturing a device using the rinse composition.

However, the problems to be solved by the present disclosure are not limited to the above-mentioned problems, and other problems not mentioned will be clearly understood by those skilled in the art from the following description.

In order to achieve the above objects, the present disclosure provides a rinse composition including: a primary alcohol having 2 to 6 carbon atoms, a glycerol ether compound, a diol compound, and water, wherein the glycerol ether compound includes a compound represented by Chemical Formula 1 below, and the diol compound includes a compound represented by Chemical Formula 2 below:

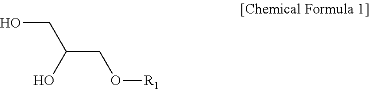

In Chemical Formula 1 above,
R₁ is a linear or branched alkyl group having 2 to 6 carbon atoms.

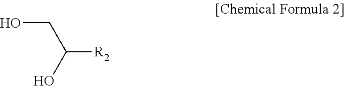

In Chemical Formula 2 above,
R₂ is hydrogen, a halogen group, or a substituted or unsubstituted linear or branched alkyl group having 1 to 3 carbon atoms.

A weight ratio of the glycerol ether compound to the diol compound may be 15:1 to 20:1.

A log P value of the primary alcohol having 2 to 6 carbon atoms may be 0 to 1.5.

The primary alcohol having 2 to 6 carbon atoms may be included in an amount of 0.05 to 25 wt % based on the total weight of the rinse composition.

The primary alcohol having 2 to 6 carbon atoms may be included in an amount of 0.1 to 20 wt % based on the total weight of the rinse composition.

The glycerol ether compound may be included in an amount of 0.00375 to 2 wt % based on the total weight of the rinse composition.

The diol compound may be included in an amount of 0.00025 to 0.1 wt % based on the total weight of the rinse composition.

A line width of a photoresist pattern to be rinsed using the rinse composition may be 200 nm or less.

In addition, the present disclosure provides a method for manufacturing a device, including: forming a photoresist film on a substrate;
exposing the photoresist film;
developing the exposed photoresist pattern to form a photoresist pattern; and
rinsing the photoresist pattern using the rinse composition.

The present disclosure can provide a rinse composition capable of securing excellent cleaning performance for resist residues while preventing damage to a pattern, such as pattern collapse, when performing a rinsing process for a micropattern formed in a photoresist process.

In addition, the present disclosure can provide a method for manufacturing a device using the rinse composition.

### BRIEF DESCRIPTION OF THE DRAWINGS

FIG. 1 shows a result of confirming a case where there is no change on a surface of a pattern in evaluating a degree of damage to a photoresist pattern.

FIG. 2 shows a result of confirming a case where damage occurs on a surface of a pattern in evaluating a degree of damage to a photoresist pattern.

### DETAILED DESCRIPTION

The present disclosure relates to a rinse composition including: a primary alcohol having 2 to 6 carbon atoms, a glycerol ether compound, a diol compound, and water, wherein the glycerol ether compound includes a compound represented by Chemical Formula 1, and the diol compound includes a compound represented by Chemical Formula 2, and to a method for manufacturing a device using the same.

The present disclosure has been completed by experimentally confirming that a rinse composition capable of securing excellent cleaning performance for resist residues while preventing damage to a pattern, such as pattern collapse, when performing a rinsing process for a micropattern formed in a photoresist process can be provided by including the glycerol ether compound and the diol compound together with the primary alcohol having 2 to 6 carbon atoms. Specifically, a line width of a photoresist pattern to be rinsed using the rinse composition may be 200 nm or less, preferably 180 nm or less.

Hereinafter, each component constituting the rinse composition of the present disclosure will be described in detail. However, the present disclosure is not limited by these components.

As used herein, the terms “comprises/includes” and/or “comprising/including” are used to mean that the presence or addition of one or more other components, in addition to the stated components, is not excluded.

### <Rinse Composition>

The rinse composition of the present disclosure includes a primary alcohol having 2 to 6 carbon atoms, a glycerol ether compound, a diol compound, and water.

### Primary Alcohol Having 2 to 6 Carbon Atoms

The primary alcohol having 2 to 6 carbon atoms of the present disclosure can serve to remove residues that are not completely removed by a developer after development of a photoresist, while preventing pattern collapse or damage to patterns by adjusting a surface tension of the rinse composition of the present disclosure and a contact angle at an interface. When an alcohol having 7 or more carbon atoms is included in the rinse composition, solubility in the rinse composition is reduced, so that the alcohol exists in a particulate form within the composition and acts as particles during a rinsing process, which may lead to a problem of causing damage, such as damage to the pattern. In this aspect, it is preferable that the primary alcohol having 2 to 6 carbon atoms is included.

The type of the primary alcohol having 2 to 6 carbon atoms is not particularly limited, and examples thereof include ethanol, 1-propanol, 2-butanol, 1-pentanol, 1-hexanol, 1-methoxy-propanol, 1-ethoxy-propanol, 1-propoxy-propanol, and the like, wherein one or more selected therefrom may be used.

It is preferable that the primary alcohol having 2 to 6 carbon atoms has a log P value, which is a partition coefficient for a solute and an organic compound (based on 1-octanol), of 0 to 1.5 in terms of securing residue removal performance of the rinse composition, but is not limited thereto.

The primary alcohol having 2 to 6 carbon atoms may be included in an amount of 0.05 to 25 wt %, preferably 0.1 to 20 wt %, and most preferably 0.5 to 10 wt %, based on the total weight of the rinse composition. When the primary alcohol having 2 to 6 carbon atoms is included in an amount less than the above range, a pattern collapse phenomenon may occur or it may be difficult to expect a sufficient residue removal effect. When the primary alcohol is included in an amount exceeding the above range, not only residues but also a resist film forming the pattern may be dissolved, thereby causing damage to the resist or lowering a residual film ratio, which may result in a problem in that it is difficult to secure a high aspect ratio of the pattern.

### Glycerol Ether Compound

The glycerol ether compound of the present disclosure can serve to adjust a surface tension of the rinse composition of the present disclosure and a contact angle at an interface, thereby preventing damage, such as pattern collapse and/or damage to the patterns.

Specifically, when an excessive amount of the primary alcohol having 2 to 6 carbon atoms is included in the rinse composition, problems such as damage to a resist film forming a pattern may occur. However, by including the glycerol ether compound together in the rinse composition, it is possible to control the composition so that damage, such as pattern collapse and/or damage to the pattern, does not occur even when the primary alcohol having 2 to 6 carbon atoms is included in a small amount. In this aspect, it is preferable to include the glycerol ether compound. When only the glycerol ether compound is included in the rinse composition, there is a limitation in adjusting a contact angle at an interface, and thus, it is preferable that the glycerol ether compound is included together with the primary alcohol having 2 to 6 carbon atoms.

The glycerol ether compound is characterized by including a compound represented by Chemical Formula 1 below:

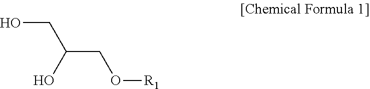

In Chemical Formula 1 above,
R₁ is a linear or branched alkyl group having 2 to 6 carbon atoms.

The compound represented by Chemical Formula 1 has a structure having a hydrophilic head and a hydrophobic tail within a molecule, which acts on a liquid interface to lower a surface tension, and the lowered surface tension can reduce a capillary force that pulls and collapses patterns. Therefore, the compound can have an excellent effect of preventing occurrence of damage, such as collapse of pattern and/or damage to the patterns, during a rinsing process even when a photoresist pattern is a micropattern having a high aspect ratio. In this respect, it is preferable that the compound represented by Chemical Formula 1 is included as the glycerol ether compound.

In the compound represented by Chemical Formula 1, when R₁ has 7 or more carbon atoms, solubility in the rinse composition is reduced, so that the compound exists in a particulate form within the composition and acts as particles during a rinsing process, which may lead to a problem of causing damage, such as damage to the pattern. In this respect, a linear or branched alkyl group having 2 to 6 carbon atoms is preferable.

Examples of the compound represented by Chemical Formula 1 include butyl glycerol ether, hexyl glycerol ether, pentyl glycerol ether, and the like, and one or more selected therefrom may be used, but are not limited thereto.

The glycerol ether compound may be included in an amount of 0.00375 to 2 wt %, preferably 0.005 to 1.5 wt %, and most preferably 0.095 to 1.2 wt %, based on the total weight of the rinse composition. When the glycerol ether compound is included in an amount less than the above range, a surface tension of the rinse composition and a contact angle at an interface cannot be sufficiently controlled, resulting in pattern collapse. When the glycerol ether compound is included in an amount exceeding the above range, damage to the resist may occur or a residual film ratio may be lowered, thereby causing a problem in that it is difficult to secure a high aspect ratio of the pattern.

### Diol Compound

The diol compound of the present disclosure refers to a compound including two hydroxyl groups within a molecule, and the diol compound may be included in terms of increasing the solubility of the glycerol ether compound in the rinse composition. Specifically, it is preferable that the glycerol ether compound and the diol compound are included in a weight ratio of 10:1 to 25:1, and preferably 15:1 to 20:1, in terms of being able to increase the solubility of the glycerol ether compound. When the weight ratio is outside the above range, it is undesirable in that solubility of the glycerol ether compound in the rinse composition is reduced, so that the glycerol ether compound exists in a particulate form within the composition and acts as particles during a rinsing process, which may lead to a problem of causing damage, such as damage to the pattern.

The diol compound is characterized by including a compound represented by Chemical Formula 2 below in terms of being able to secure solubility in the rinse composition while increasing solubility of the glycerol ether compound in the rinse composition.

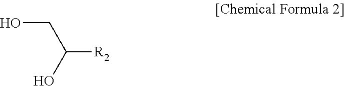

In Chemical Formula 2 above,
R₂ is hydrogen, a halogen group, or a substituted or unsubstituted linear or branched alkyl group having 1 to 3 carbon atoms.

In the compound represented by Chemical Formula 2, when R₂ is a linear or branched alkyl group and has 4 or more carbon atoms, solubility in the rinse composition is reduced, so that the compound exists in a particulate form within the composition and acts as particles during a rinsing process, thereby causing damage such as damage to the patterns, or remains as residues on the patterns after the rinsing process, adversely affecting pattern reliability. In this respect, a linear or branched alkyl group having 1 to 3 carbon atoms is preferable. When the linear or branched alkyl group of R₂ is substituted, it may be substituted with a halogen group.

Examples of the compound represented by Chemical Formula 2 include 3-methyl-1,2-propanediol, 3-chloro-1,2-propanediol, and 1,2-butanediol, and one or more selected therefrom may be used.

The diol compound may be included in an amount of 0.00025 to 0.1 wt %, preferably 0.00025 to 0.075 wt %, and most preferably 0.00025 to 0.067 wt %, based on the total weight of the rinse composition. When the diol compound is included in an amount less than the above range, solubility of the glycerol ether compound cannot be sufficiently increased. When the diol compound is included in an amount exceeding the above range, a problem may occur in that the diol compound is not completely dissolved and exists in a particulate form within the rinse composition, thereby affecting reliability during a rinsing process.

### Water

The rinse composition of the present disclosure includes water in addition to the primary alcohol having 2 to 6 carbon atoms, the glycerol ether compound, and the diol compound. The water is not particularly limited, but it is preferable to use deionized water, preferably deionized water for semiconductor processes. The water may preferably have a resistivity of 18 Ω·cm or more.

The water may be included as a balance with respect to a total of 100 wt % of the rinse composition. The balance refers to a remaining amount such that a total weight of the composition, including essential components of the rinse composition of the present disclosure and any other additional components, becomes 100 wt %.

### <Manufacturing Method of Device>

In addition, the present disclosure provides a method for manufacturing a device using the above-described rinse composition.

The method for manufacturing a device is not particularly limited, as long as the device can be manufactured according to a known manufacturing method of a device, except for using the rinse composition according to the present disclosure.

In one embodiment of the present disclosure, the method for manufacturing a device includes:
forming a photoresist film on a substrate;
exposing the photoresist film;
developing the exposed photoresist pattern to form a photoresist pattern; and
rinsing the photoresist pattern using the rinse composition.

In addition, the method may further include drying the rinsed photoresist pattern.

Hereinafter, the present disclosure will be described in more detail by way of examples.

However, the following Examples are intended to more specifically describe the present disclosure, and the scope of the present disclosure is not limited by the following Examples. The following Examples may be appropriately modified or changed by those skilled in the art within the scope of the present disclosure.

In addition, unless otherwise specified, “%” and “parts” indicating contents below are based on weight.

### Examples and Comparative Examples

### Examples 1 to 24 and Comparative Examples 1 to 6: Preparation of Rinse Compositions

Rinse compositions of Examples 1 to 24 and Comparative Examples 1 to 6 were respectively prepared according to the compositions and contents shown in Table 1 below.

TABLE 1

| | Rinse composition (wt %) | | | | | | | | | | | | | |
|---|---|---|---|---|---|---|---|---|---|---|---|---|---|---|
| | | | | | | | Glycerol ether | | | | | | | |
| | Alcohol | | | | | | compound | | | | Diol | | | |
| | A-1 | A-2 | A-3 | A-4 | A-5 | A-6 | B-1 | B-2 | B-3 | B-4 | C-1 | C-2 | C-3 | Water |
| Example 1 | 10 | | | | | | 0.095 | | | | 0.005 | | | Balance |
| Example 2 | | 10 | | | | | 0.095 | | | | 0.005 | | | Balance |
| Example 3 | | | 0.5 | | | | 0.095 | | | | 0.005 | | | Balance |
| Example 4 | 0.05 | | | | | | 0.095 | | | | 0.005 | | | Balance |
| Example 5 | 0.1 | | 0.1 | | | | 0.095 | | | | 0.005 | | | Balance |
| Example 6 | 20 | | | | | | 0.095 | | | | 0.005 | | | Balance |
| Example 7 | 25 | | | | | | 0.095 | | | | 0.005 | | | Balance |
| Example 8 | | | 0.5 | | | | | 2.0 | | | 0.1 | | | Balance |
| Example 9 | | | 0.5 | | | | | 1.5 | | | 0.075 | | | Balance |
| Example 10 | | | 0.5 | | | | | 1 | | | 0.05 | | | Balance |
| Example 11 | | | 0.5 | | | | | 0.5 | | | 0.025 | | | Balance |
| Example 12 | | | 0.5 | | | | | 0.1 | | | 0.005 | | | Balance |
| Example 13 | | | 0.5 | | | | | 0.005 | | | 0.00025 | | | Balance |
| Example 14 | | | 0.5 | | | | | 0.095 | | | 0.005 | | | Balance |
| Example 15 | | | 0.5 | | | | 0.095 | | | | | 0.005 | | Balance |
| Example 16 | | | | 5 | | | 0.095 | | | | 0.005 | | | Balance |
| Example 17 | | | 0.5 | | | | | 0.095 | | | 0.0005 | | | Balance |
| Example 18 | | | 0.5 | | | | | 0.095 | | | 0.005 | | | Balance |
| Example 19 | | | 0.5 | | | | | 0.095 | | | 0.006 | | | Balance |
| Example 20 | | | 0.5 | | | | | 0.095 | | | 0.0095 | | | Balance |
| Example 21 | | | | | 10 | | 0.1 | | | | 0.005 | | | Balance |
| Example 22 | | | 0.5 | | | | | 0.001 | | | 0.00005 | | | Balance |
| Example 23 | | | 0.5 | | | | 0.001 | | | | 0.005 | | | Balance |
| Example 24 | | | 0.5 | | | | 2.5 | | | | 0.005 | | | Balance |
| Comparative | | | 0.5 | | | | 0.1 | | | | | | | Balance |
| Example 1 | | | | | | | | | | | | | | |
| Comparative | | | 0.5 | | | | | | | | 0.005 | | | Balance |
| Example 2 | | | | | | | | | | | | | | |
| Comparative | | | 0.5 | | | | | | 0.095 | | 0.005 | | | Balance |
| Example 3 | | | | | | | | | | | | | | |
| Comparative | | | 0.5 | | | | | | | 0.095 | 0.005 | | | Balance |
| Example 4 | | | | | | | | | | | | | | |
| Comparative | | | 0.5 | | | | | | | 0.095 | | | 0.005 | Balance |
| Example 5 | | | | | | | | | | | | | | |
| Comparative | | | | | | 0.5 | 0.1 | | | | 0.005 | | | Balance |
| Example 6 | | | | | | | | | | | | | | |

A-1: Ethanol (CAS 64-17-5)
A-2:1-Propanol (CAS 71-23-8)
A-3:1-Pentanol (CAS 71-41-0)
A-4:2-Butanol (CAS 78-92-2)
A-5:1-Methoxy-propanol (CAS 107-98-2)
A-6:1-Heptanol (CAS 111-70-6)
B-1: Butyl glycerol ether (CAS 624-52-2)
B-2: Hexyl glycerol ether (CAS 10305-38-1)
B-3:2,3-Dimethoxypropan-1-ol (CAS 40453-77-8)
B-4: Glycerin (CAS 56-81-5)
C-1:3-Methyl-1,2-propanediol
C-2:3-Chloro-1,2-propanediol
C-3: Triethylene glycol

### Experimental Example

### Photoresist Pattern Fabrication

A lower anti-reflection film (DUV42P-6, Nissan Chemical Industries) was spin-coated on a silicon wafer and then heated at 215° C. for 90 seconds to form a film having a thickness of 600 Å. A PHS-type photosensitizer (KTF-5664, Dongwoo Fine-Chem) was spin-coated on an upper portion of the silicon wafer on which the film was formed, thereby forming a photoresist thin film, followed by soft baking in an oven at 100° C. for 60 seconds. Subsequently, the photoresist film was exposed using a scanner equipped with a KrF laser and post-baked in an oven at 100° C. for 60 seconds. Thereafter, development was performed by immersion in a 2.38 wt % tetramethylammonium hydroxide (TMAH) aqueous solution for 60 seconds.

Thereafter, development residues on the upper portion of the silicon wafer were removed using deionized water. 30 mL of the rinse composition prepared in the above Examples and Comparative Examples was applied on a surface of the washed silicon wafer for 10 seconds, and then dried by high-speed spinning to obtain a 180 nm L/S pattern.

### (1) Evaluation of Pattern Collapse

A degree of collapse of a 180 nm L/S pattern was observed using a CD-SEM (Hitachi), and evaluated according to the following evaluation criteria. The results are shown in Table 2 below.

### <Evaluation Criteria>

∘: No pattern collapse occurred.
Δ: Collapse occurred only in an edge pattern.
x: Collapse occurred in edge and center patterns.

### (2) Evaluation of Degree of Damage to Photoresist Pattern

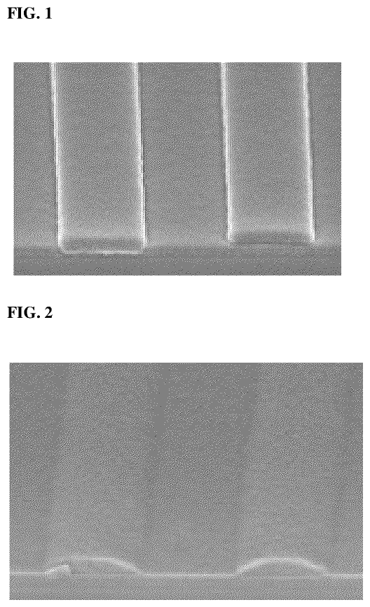

Pattern substrates fabricated through photolithography were dipped in each rinse composition at room temperature for 20 seconds and then dried. A surface condition of the pattern was observed using a scanning electron microscope (Regulus 8230, manufactured by Hitachi) according to the criteria shown in FIGS. 1 and 2, and evaluated based on the following evaluation criteria. The results are shown in Table 2 below.

### <Evaluation Criteria>

∘: No change in a pattern surface.
x: A pattern surface was dissolved or deformed.

### (3) Particle Evaluation

The rinse compositions prepared in the above Examples and Comparative Examples were filtered through a filter having a size of 0.01 μm, allowed to flow for approximately 30 minutes and left to stand, and then a number of particles having a size of 100 nm was measured using a liquid particle counter (KS-18F, manufactured by Rion Co., Ltd.). The results were evaluated according to the following evaluation criteria and are shown in Table 2 below.

### <Evaluation Criteria>

∘: Less than 100
Δ: 100 or more and less than 300
x: 300 or more

TABLE 2

| | Pattern | Photoresist | |
|---|---|---|---|
| Division | Collapse | Damage | Particles |
| Example 1 | ◯ | ◯ | ◯ |
| Example 2 | ◯ | ◯ | ◯ |
| Example 3 | ◯ | ◯ | ◯ |
| Example 4 | Δ | ◯ | ◯ |
| Example 5 | ◯ | ◯ | ◯ |
| Example 6 | ◯ | ◯ | ◯ |
| Example 7 | ◯ | Δ | ◯ |
| Example 8 | ◯ | ◯ | ◯ |
| Example 9 | ◯ | ◯ | ◯ |
| Example 10 | ◯ | ◯ | ◯ |
| Example 11 | ◯ | ◯ | ◯ |
| Example 12 | ◯ | ◯ | ◯ |
| Example 13 | ◯ | ◯ | ◯ |
| Example 14 | ◯ | ◯ | ◯ |
| Example 15 | ◯ | ◯ | ◯ |
| Example 16 | Δ | ◯ | ◯ |
| Example 17 | ◯ | ◯ | Δ |
| Example 18 | ◯ | ◯ | ◯ |
| Example 19 | ◯ | ◯ | ◯ |
| Example 20 | Δ | ◯ | ◯ |
| Example 21 | ◯ | Δ | ◯ |
| Example 22 | Δ | ◯ | ◯ |
| Example 23 | Δ | ◯ | ◯ |
| Example 24 | ◯ | Δ | Δ |
| Comparative Example 1 | ◯ | Δ | X |
| Comparative Example 2 | X | ◯ | ◯ |
| Comparative Example 3 | X | ◯ | ◯ |
| Comparative Example 4 | X | ◯ | ◯ |
| Comparative Example 5 | X | Δ | X |
| Comparative Example 6 | ◯ | X | Δ |

Referring to the above experimental results, it can be confirmed that in Examples 1 to 24 according to the present disclosure, by including a primary alcohol having 2 to 6 carbon atoms, a glycerol ether compound, and a diol compound together, a pattern does not collapse, no change occurs on a surface of a photoresist pattern, and the number of particles is less than 100, indicating that all of the diol compound is dissolved in the rinse composition.

In contrast, in Comparative Example 1, which does not include a diol compound, it was confirmed that the glycerol ether compound was not completely dissolved in the composition and acted as particles, thereby causing damage to the photoresist. In Comparative Examples 2 to 5, which do not include a glycerol ether compound or include a compound not falling within the range of compounds represented by Chemical Formula 1, it can be confirmed that pattern collapse occurred because surface tension could not be sufficiently adjusted with only a small amount of the primary alcohol having 2 to 6 carbon atoms. In particular, in the case of Comparative Example 5, which includes a compound not falling within the range of compounds represented by Chemical Formula 2 together, it can be confirmed that not only pattern collapse occurred but also damage occurred to the photoresist pattern due to the presence of a large number of particles. Additionally, in Comparative Example 6, which includes a primary alcohol having more than 6 carbon atoms, it can be confirmed that the alcohol acts as a particle and causes damage to the photoresist.

What is claimed is:

1. A rinse composition comprising: a primary alcohol having 2 to 6 carbon atoms, a glycerol ether compound, a diol compound, and water,
wherein the glycerol ether compound includes a compound represented by Chemical Formula 1 below, and
the diol compound includes a compound represented by Chemical Formula 2 below: 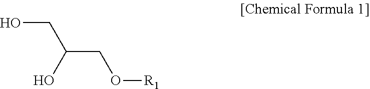
wherein R₁ is a linear or branched alkyl group having 2 to 6 carbon atoms, and 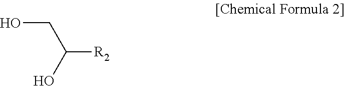
wherein R₂ is hydrogen, a halogen group, or a substituted or unsubstituted linear or branched alkyl group having 1 to 3 carbon atoms.

2. The rinse composition of claim 1, wherein a weight ratio of the glycerol ether compound to the diol compound is 15:1 to 20:1.

3. The rinse composition of claim 1, wherein a log P value of the primary alcohol having 2 to 6 carbon atoms is 0 to 1.5.

4. The rinse composition of claim 1, wherein the primary alcohol having 2 to 6 carbon atoms is included in an amount of 0.05 to 25 wt % based on the total weight of the rinse composition.

5. The rinse composition of claim 4, wherein the primary alcohol having 2 to 6 carbon atoms is included in an amount of 0.1 to 20 wt % based on the total weight of the rinse composition.

6. The rinse composition of claim 1, wherein the glycerol ether compound is included in an amount of 0.00375 to 2 wt % based on the total weight of the rinse composition.

7. The rinse composition of claim 1, wherein the diol compound is included in an amount of 0.00025 to 0.1 wt % based on the total weight of the rinse composition.

8. The rinse composition of claim 1, wherein a line width of a photoresist pattern to be rinsed using the rinse composition is 200 nm or less.

9. A method for manufacturing a device, the method comprising:
forming a photoresist film on a substrate;
exposing the photoresist film;
developing the exposed photoresist pattern to form a photoresist pattern; and
rinsing the photoresist pattern using the rinse composition of claim 1.
